(19) United States
(12) Patent Application Publication
(10) Pub. No.: US 2026/0072355 A1
(43) Pub. Date: Mar. 12, 2026

(54) METHOD OF ENHANCING ETCH-RESISTANCE OF PHOTORESIST PATTERN, AND METHOD OF MANUFACTURING SEMICONDUCTOR DEVICE USING PHOTORESIST PATTERN

(71) Applicant: Samsung Electronics Co., Ltd., Suwon-si (KR)

(72) Inventors: Jooyoung Song, Suwon-si (KR); Sukjoon Hong, Ansan-si (KR); Suk Koo Hong, Suwon-si (KR); Youngchan Kim, Ansan-si (KR); Jungmin Hong, Ansan-si (KR)

(73) Assignee: Industry-University Cooperation Foundation Hanyang University ERICA Campus, Ansan-si (KR)

(21) Appl. No.: 19/080,230

(22) Filed: Mar. 14, 2025

(30) Foreign Application Priority Data
Sep. 11, 2024 (KR) 10-2024-0124241

(51) Int. Cl. G03F 7/40; G03F 7/00; G03F 7/039; H01L 21/308; H01L 21/311; H01L 21/3213

(52) U.S. Cl. CPC G03F 7/40; G03F 7/039; G03F 7/70033; H10P 50/691; H10P 50/71; H10P 50/73

(57) ABSTRACT

Provided is a method of enhancing etch resistance of a photoresist pattern, the method including forming a photoresist film including a photoresist composition including a polymer, forming a photoresist pattern by patterning the photoresist film, and irradiating the photoresist pattern with a laser, wherein the etch resistance of the photoresist pattern irradiated with the laser is enhanced.

### CROSS-REFERENCE TO RELATED APPLICATION

This application is based on and claims priority under 35 U.S.C. § 119 to Korean Patent Application No. 10-2024-0124241, filed on Sep. 11, 2024, in the Korean Intellectual Property Office, the disclosure of which is incorporated by reference herein in its entirety.

### BACKGROUND

The inventive concept relates to a method of enhancing etch resistance of a photoresist pattern, and a method of manufacturing a semiconductor device using the photoresist pattern, and particularly, to a method of enhancing etch resistance of a photoresist pattern using an acrylate-based photoresist composition, and a method of manufacturing a semiconductor device using the photoresist pattern.

With the development of electronics technology, down-scaling of semiconductor devices has been rapidly progressing in recent years. As a result, the patterns of the semiconductor devices are also miniaturized. To implement the fine patterns, the thickness of the photoresist composition used in implementing the patterns is also decreasing. As the thickness of the photoresist composition decreases, the difficulty of the etching process for implementing the patterns increases. Accordingly, there is a need for a method of implementing fine patterns even at low thicknesses.

### SUMMARY

The inventive concept provides a method of enhancing etch resistance of a photoresist pattern without deteriorating patterning performance, and a method of manufacturing a semiconductor device using the photoresist pattern.

According to an aspect of the inventive concept, there is provided a method of enhancing etch resistance of a photoresist pattern, the method including forming a photoresist film comprising a photoresist composition comprising a polymer, forming a photoresist pattern by patterning the photoresist film, and irradiating the photoresist pattern with a laser, wherein the etch resistance of the photoresist pattern irradiated with the laser is enhanced.

According to another aspect of the inventive concept, there is provided a method of enhancing etch resistance of a photoresist pattern, the method including forming a photoresist film comprising a photoresist composition comprising an acrylate-based polymer, forming a photoresist pattern by patterning the photoresist film, and irradiating the photoresist pattern with a laser, wherein the irradiating of the photoresist pattern with the laser is performed without creating a separate chamber atmosphere for laser irradiation, and the etch resistance of the photoresist pattern irradiated with the laser is enhanced.

### BRIEF DESCRIPTION OF THE DRAWINGS

Embodiments will be more clearly understood from the following detailed description taken in conjunction with the accompanying drawings in which:

FIG. 1 is a flowchart of a method of manufacturing a semiconductor device, according to some embodiments;

FIGS. 2 to 7 are diagrams illustrating a method of manufacturing a semiconductor device, according to some embodiments;

FIGS. 8A to 8C are diagrams of etching results using a photoresist pattern after enhancing the etch resistance of the photoresist pattern, according to some embodiments;

FIGS. 9A to 9C are diagrams of etching results using a photoresist pattern, according to a comparative example; and

FIGS. 10A and 10B are diagrams of etching results using a photoresist pattern according to the fluence of a laser used for irradiation.

### DETAILED DESCRIPTION OF THE EMBODIMENTS

Hereinafter, embodiments are described in detail with reference to the accompanying drawings. The same reference numerals are used for the same components in the drawings, and redundant description thereof is omitted.

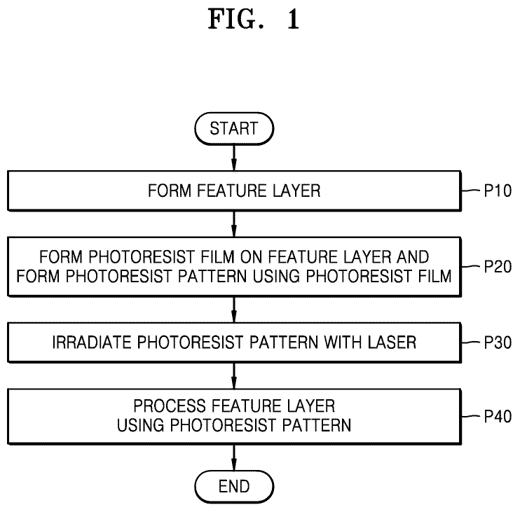

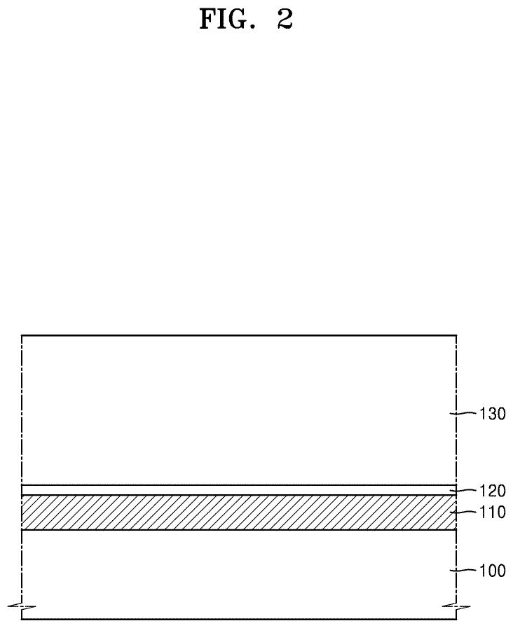

FIG. 1 is a flowchart illustrating a method of manufacturing a semiconductor device, according to some embodiments. FIGS. 2 to 7 are diagrams illustrating a method of manufacturing a semiconductor device, according to some embodiments.

Referring to FIGS. 1 and 2, a feature layer 110 may be formed on a substrate 100 (P10), and a photoresist film 130 may be formed on the feature layer 110 using a photoresist composition (P20).

In some embodiments, the photoresist film 130 may include the photoresist composition including an acrylate-based polymer. The photoresist composition may include, for example, polymethyl methacrylate (PMMA).

However, the inventive concept is not limited thereto. The photoresist composition may include a polymer material which may be used as a photoresist composition for extreme ultraviolet (EUV) photolithography. For example, the photoresist composition may include polyvinylpyrrolidone (PVP).

In some embodiments, the photoresist composition may not include a photoinitiator for enhancing the etch resistance by laser irradiation, such as Irgacure 651 (2,2-dimethoxy-2-phenylacetophenone). That is, the photoresist composition, according to some embodiments, may not include a separate photoinitiator for promoting crosslinking between acrylate-based polymers by laser irradiation. Since the photoresist composition does not include the photoinitiator for enhancing the etch resistance, the performance deterioration of the photoresist pattern due to the photoinitiator for enhancing the etch resistance may be prevented during the process of forming the photoresist pattern using the photoresist composition.

The photoresist composition may further include a solvent. The solvent included in the photoresist composition may include an organic solvent. In some embodiments, the solvent may include at least one of an ether, an alcohol, a glycol ether, an aromatic hydrocarbon compound, a ketone, and an ester. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, 3-methoxyethyl propionate, 3-ethoxyethyl propionate, methyl 3-ethoxypropionate, methyl pyruvate, ethyl pyruvate, ethyl acetate, butyl acetate, ethyl lactate, and butyl lactate. These solvents may be used alone or in combination of at least two thereof.

In the photoresist composition according to some embodiments, the solvent may be included in the remaining amount excluding main components including the acrylate-based polymer. In some embodiments, the solvent may be included in an amount of about 0.1% by weight to about 99.0% by weight, based on the total weight of the photoresist composition.

In some embodiments, the photoresist composition, according to some embodiments, may further comprise at least one selected from a surfactant, a dispersant, and a coupling agent.

The surfactant may improve the coating uniformity and wettability of the photoresist composition. In some embodiments, the surfactant may include, but is not limited to, sulfuric acid ester salt, sulfonate salt, phosphoric acid ester, soap, amine salt, quaternary ammonium salt, polyethylene glycol, alkylphenol-ethylene oxide adduct, polyhydric alcohol, nitrogen-containing vinyl polymer, or a combination thereof. For example, the surfactant may include alkylbenzene sulfonate, alkylpyridinium salt, polyethylene glycol, or quaternary ammonium salt. When the photoresist composition includes the surfactant, the surfactant may be included therein in an amount of about 0.001% by weight to about 3% by weight, based on the total weight of the photoresist composition.

The dispersant may ensure that each component constituting the photoresist composition is uniformly dispersed within the photoresist composition. In some embodiments, the dispersant may include, but is not limited to, epoxy resin, polyvinyl alcohol, polyvinyl butyral, PVP, glucose, sodium dodecyl sulfate, sodium citrate, oleic acid, linoleic acid, or a combination thereof. When the photoresist composition includes the dispersant, the dispersant may be included therein in an amount of about 0.001% by weight to about 5% by weight, based on the total weight of the photoresist composition.

The coupling agent may improve adhesion with a lower film when coating the photoresist composition onto the lower film. In some embodiments, the coupling agent may include a silane coupling agent. The silane coupling agent may include, but is not limited to, vinyltrimethoxysilane, vinyltriethoxysilane, vinyl trichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be included therein in an amount of about 0.001% by weight to about 5% by weight, based on the total weight of the photoresist composition.

When the solvent includes only an organic solvent in the photoresist composition according to some embodiments, the photoresist composition may further include water. In this case, the water content in the photoresist composition may be from about 0.001% by weight to about 0.1% by weight.

The substrate 100 may include a semiconductor substrate. For example, the substrate 100 may include an elemental semiconductor material, such as silicon (Si) or germanium (Ge), or a compound semiconductor material, such as silicon germanium (SiGe), silicon carbide (SiC), gallium arsenide (GaAs), indium arsenide (InAs), or indium phosphide (InP).

The feature layer 110 may include an insulating film, a conductive film, or a semiconductor film. For example, the feature layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

In some embodiments, as shown in FIG. 2, a lower film 120 may be formed on the feature layer 110 before forming the photoresist film 130 thereon. In this case, the photoresist film 130 may be formed on the lower film 120. The lower film 120 may control diffuse reflection of light from a light source used during an exposure process for manufacturing a semiconductor device or may absorb reflected light from the feature layer 110 below the lower film 120.

In some embodiments, the lower film 120 may include an organic or inorganic anti-reflective coating (ARC) material for a KrF excimer laser, an ArF excimer laser, an EUV laser, or any other light source. In some embodiments, the lower film 120 may include a bottom anti-reflective coating (BARC) film or a developable bottom anti-reflective coating (DBARC) film.

In other embodiments, the lower film 120 may include an organic component having a light-absorbing structure. The light-absorbing structure may include, for example, a hydrocarbon compound having one or greater benzene rings or a structure in which the benzene rings are fused. The lower film 120 may be formed to have a thickness of about 20 nm to about 100 nm but is not limited thereto. In some embodiments, the lower film 120 may be omitted.

To form the photoresist film 130, the photoresist composition according to some embodiments may be coated on the lower film 120 and then heat-treated. The coating may be performed by a method, such as spin coating, spray coating, or dip coating. The process of heat-treating the photoresist composition may be performed at a temperature of about 80° C. to about 300° C. for about 10 seconds to about 100 seconds but is not limited thereto. The thickness of the photoresist film 130 may be about several tens to about several hundred times the thickness of the lower film 120. The photoresist film 130 may be formed to have a thickness of about 100 nm to about 6 μm but is not limited thereto.

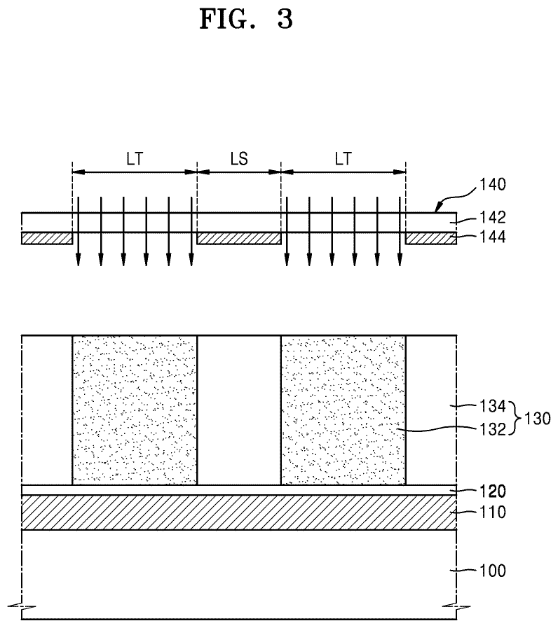

Referring to FIGS. 1 and 3, a first area 132, which is part of the photoresist film 130, may be exposed (P20).

In some embodiments, to expose the first area 132 of the photoresist film 130, a photomask 140 having a plurality of light-shielding areas LS and a plurality of light-transmitting areas LT may be aligned with a certain position on the photoresist film 130, and the first area 132 of the photoresist film 130 may be exposed through the plurality of light-transmitting areas LT of the photomask 140. In some embodiments, an EUV laser (13.5 nm) may be used to expose the first area 132 of the photoresist film 130.

The photomask 140 may include a transparent substrate 142 and a plurality of light-shielding patterns 144 formed in the plurality of the light-shielding areas LS on the transparent substrate 142. The transparent substrate 142 may include quartz. The plurality of light-shielding patterns 144 may include chromium (Cr). The plurality of light-transmitting areas LT may be defined by the plurality of light-shielding patterns 144. According to some embodiments, a reflective photomask (not shown) for EUV exposure may be used, instead of the photomask 140, to expose the first area 132 of the photoresist film 130.

In some embodiments, the photoresist film 130 may be soft-baked after performing the process described with reference to FIG. 2 and before performing the process described with reference to FIG. 3. The soft-baking may be performed at a temperature of about 50° C. to about 100° C. for about 5 minutes to about 10 minutes but is not limited thereto.

In some embodiments, after exposing the first area 132 of the photoresist film 130 according to the process described with reference to FIG. 3, the photoresist film 130 may be annealed. The annealing may be performed at a temperature of about 50° C. to about 400° C. for about 10 seconds to about 100 seconds but is not limited thereto.

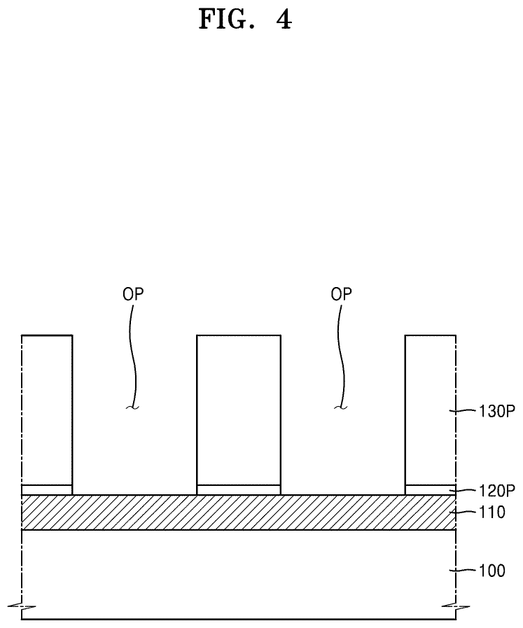

Referring to FIGS. 1 and 4, the photoresist film 130 may be baked to remove the first area 132 of the photoresist film 130 (P20). As a result, photoresist patterns 130P including unexposed second areas 134 of the photoresist film 130 may be formed.

The photoresist patterns 130P may include a plurality of openings OP. After the photoresist patterns 130P are formed, portions of the lower film 120 exposed through the plurality of openings OP may be removed to form lower patterns 120P.

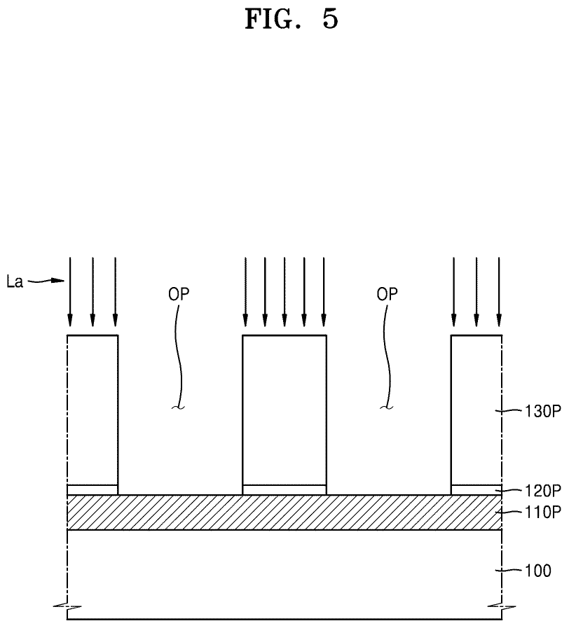

Referring to FIGS. 1 and 5, the photoresist patterns 130P may be irradiated with a laser La (P30).

The materials irradiated with the laser La to form the photoresist patterns 130P may be crosslinked, thereby enhancing the etch resistance of the photoresist patterns 130P.

In some embodiments, the laser La may include a UV laser having a wavelength of about 355 nm. In other embodiments, the laser La may include a continuous-wave laser having a wavelength of about 532 nm. Since the laser La used in FIG. 5 includes a UV laser or a continuous-wave laser, the laser La may be used for irradiation without creating a process atmosphere using a separate chamber, unlike the case of using an electron beam (E-beam).

In some embodiments, the fluence of the laser La may be from about 0.3 J/cm² to about 1.2 J/cm². When the fluence of the laser La is 0.3 J/cm² or less, the etch resistance of the photoresist patterns 130P may not be enhanced because the materials constituting the photoresist patterns 130P are not easily crosslinked even when irradiated with the laser La. On the other hand, when the fluence of the laser La is 1.2 J/cm² or greater, the structure of the materials constituting the photoresist patterns 130P irradiated with the laser La may collapse because the fluence of the laser La is too high, thereby weakening the etch resistance of the photoresist patterns 130P.

In some embodiments, the irradiation time of the laser La in the P30 process may be from about 0.05 seconds to about 2 seconds. When the irradiation time of the laser La is about 0.05 seconds or less, the materials constituting the photoresist patterns 130P may not be sufficiently cross-linked. On the other hand, when the irradiation time of the laser La is about 2 seconds or greater, the structure of the materials constituting the photoresist patterns 130P may collapse, thereby weakening the etch resistance of the photoresist patterns 130P.

In some embodiments, the process temperature of the P30 process may be about 25° C., i.e., room temperature.

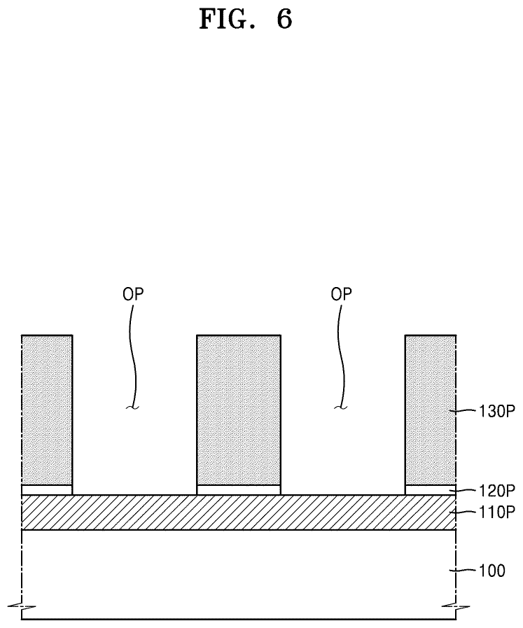

Referring to FIGS. 1 and 6, the feature layer 110 may be processed using the photoresist patterns 130P irradiated with a laser (P40).

To process the feature layer 110, the feature layer 110 exposed through the openings OP of the photoresist patterns 130P may be etched.

In some embodiments, the etching process may include a reactive ion etching (RIE) process.

Patterned feature patterns 110P may be formed through the openings OP between the photoresist patterns 130P during the P40 process.

In some embodiments, various processes may be further performed, such as a process of implanting impurity ions into the feature layer 110 to process the feature layer 110, a process of forming an additional film on the feature layer 110 through the openings OP, and a process of deforming a portion of the feature layer 110 through the openings OP. FIG. 4 illustrates a case where the feature layer 110 exposed through the openings OP is etched to form the feature patterns 110P, as an example of a process of processing the lower film 120.

In other embodiments, in the process described with reference to FIG. 2, the process of forming the feature layer 110 may be omitted. In this case, the substrate 100 may be processed using the photoresist patterns 130P, instead of the P40 process described with reference to FIGS. 1 and 6. For example, various processes may be performed, such as a process of etching a portion of the substrate 100 using the photoresist patterns 130P, a process of implanting impurity ions into a partial area of the substrate 100, a process of forming an additional film on the substrate 100 through the openings OP, and a process of deforming a portion of the substrate 100 through the openings OP.

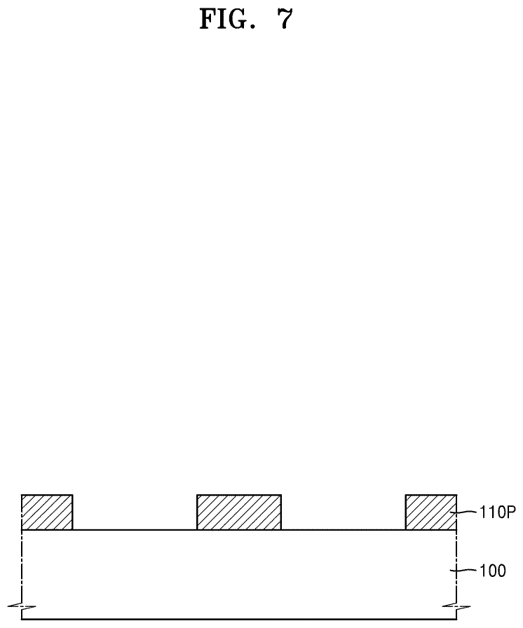

Next, referring to FIG. 7, the photoresist patterns 130P and the lower patterns 120P remaining on the feature patterns 110P may be removed. An ashing and strip process may be used to remove the photoresist patterns 130P and the lower patterns 120P.

In a method of enhancing the etch resistance of a photoresist pattern and a method of manufacturing a semiconductor device according to some embodiments, the photoresist composition including an acrylate-based polymer may be used to form the photoresist film 130, the photoresist film 130 may be patterned to form the photoresist patterns 130P, and the photoresist patterns 130P may be irradiated with a laser to enhance the etch resistance thereof, and the feature patterns 110P may be formed using the photoresist patterns 130P.

Since the photoresist composition does not include the photoinitiator for enhancing the etch resistance by laser irradiation, such as Irgacure 651 (2,2-dimethoxy-2-phenylacetophenone), deterioration of patterning performance of the photoresist patterns 130P formed from the photoresist film 130 including the photoresist composition may be prevented.

In addition, the etch resistance of the photoresist patterns 130P may be enhanced by irradiating the same with the laser La, thereby faithfully implementing the feature patterns 110P even through the low-thickness photoresist patterns 130P.

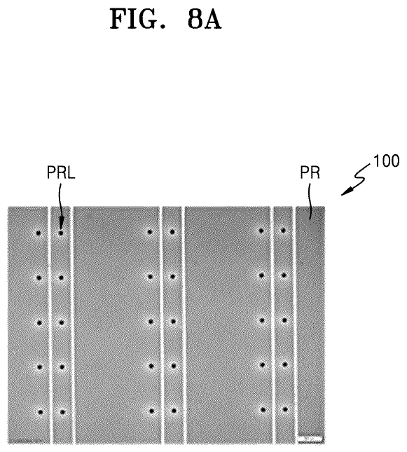

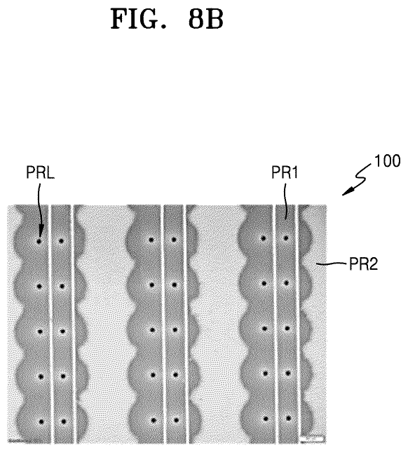

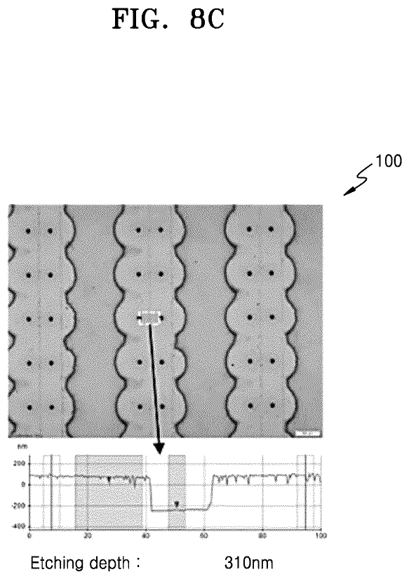

Hereinafter, the method of forming the pattern and the method of manufacturing the semiconductor device may be described with reference to FIGS. 8A to 10B.

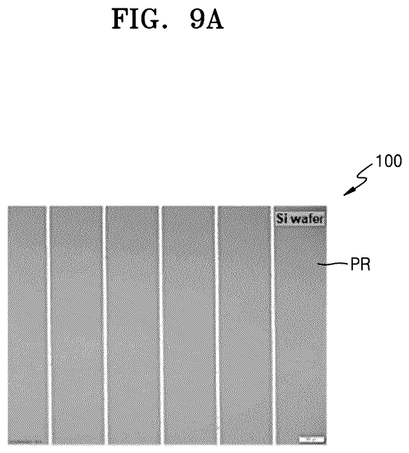

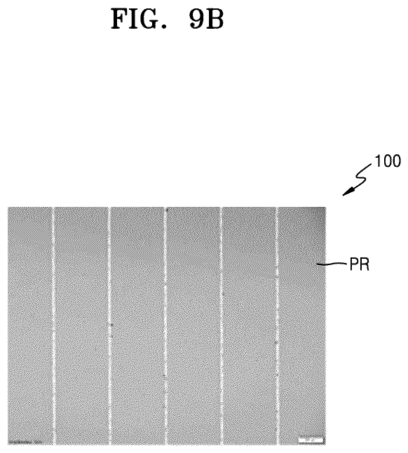

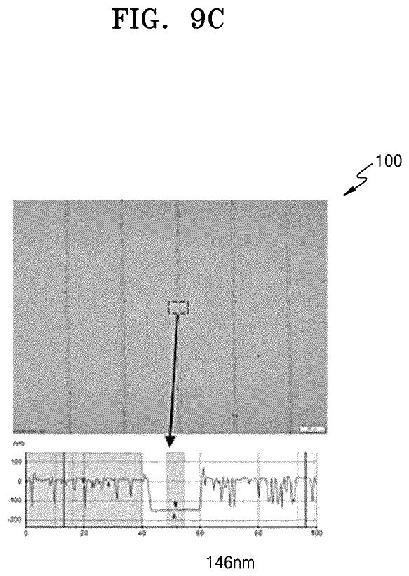

FIGS. 8A to 8C are diagrams of etching results using a photoresist pattern after enhancing the etch resistance of the photoresist pattern, according to some embodiments. FIGS. 9A to 9C are diagrams of etching results using a photoresist pattern, according to a comparative example.

Specifically, FIG. 8A is a diagram of a result of forming a photoresist film PR and irradiating a partial area of the photoresist film PR with a laser, FIG. 8B is a diagram of a result of performing an ashing process on the result of FIG. 8A, and FIG. 8C is a diagram of a result of performing an etching process on the result in FIG. 8B. On the other hand, FIG. 9A is a diagram of a result of forming the photoresist film PR but not irradiating the photoresist film PR with a laser, FIG. 9B is a diagram of a result of performing an ashing process on the result of FIG. 9A, and FIG. 9C is a diagram of a result of performing an etching process on the result in FIG. 9B.

In FIG. 8A, PMMA was first dissolved using propylene glycol methyl ether acetate (PGMEA) as a solvent, and a mixed solution including about 5% by weight of PMMA was prepared. Next, the surface of the substrate 100 was plasma-treated using O₂ gas at a flow rate of about 25 sccm for about 1 minute, and then the mixed solution was spin-coated to form the photoresist film PR with a thickness of 100 nm.

Next, in FIG. 8A, a partial area PRL of the photoresist film PR was irradiated with a UV laser having a laser fluence of about 0.6 J/cm² for about 0.05 seconds.

Next, in FIG. 8B, an ashing process was performed by a capacitively coupled plasma (CCP) method. The ashing process was performed on the photoresist film PR for about 8 seconds using O₂ gas at a flow rate of about 20 sccm with a bias power of about 50 W. As a result, the first photoresist film PR1 adjacent to the laser-irradiated area PRL in FIG. 8A was less removed by the ashing process than the second photoresist film PR2 not irradiated with a laser. Accordingly, there was a difference of about 40 nm between the thickness of the first photoresist film PR1 and the thickness of the second photoresist film PR2. That is, when comparing the thickness of the first photoresist film PR1 irradiated with a laser with the thickness of the second photoresist film PR2 not irradiated with a laser after performing the ashing process, it may be seen that the etching resistance of the first photoresist film PR1 irradiated with the laser is superior to that of the second photoresist film PR2 that is not irradiated with the laser.

Next, in FIG. 8C, the RIE process was performed by an inductively coupled plasma (ICP) method using the first photoresist film PR1 and the second photoresist film PR2. During the etching process, the substrate 100 was etched for about 1 minute using C₄F₈ gas at a flow rate of about 40 sccm, SF₆ gas at a flow rate of about 15 sccm, and O₂ gas at a flow rate of about 40 sccm. As a result of the etching process, the thickness of the substrate 100 etched using the laser-irradiated first photoresist film PR1 was about 310 nm.

In FIG. 9A, the photoresist film PR was formed by the same method under the same conditions as in FIG. 8A, but the photoresist film PR was not irradiated with a laser.

Next, in FIG. 9B, the ashing process was performed by the same method under the same conditions as in FIG. 8B.

Next, in FIG. 9C, the etching process was performed by the same method under the same conditions as in FIG. 8C. As a result of the etching process, the thickness of the substrate 100 etched using the photoresist film PR was about 146 nm. Referring to FIGS. 8C and 9C, it may be seen that the thickness of the substrate 100 etched using the first photoresist film PR1 of FIG. 8C irradiated with the laser is about 310 nm, whereas the thickness of the substrate 100 etched using the photoresist film PR of FIG. 9C not irradiated with a laser is about 146 nm. That is, since the etch resistance of the first photoresist film PR1 irradiated with the laser is superior to that of the photoresist film PR not irradiated with laser, it may be seen that the thickness of the substrate 100 etched using the first photoresist film PR1 is greater than that of the substrate 100 etched using the photoresist film PR.

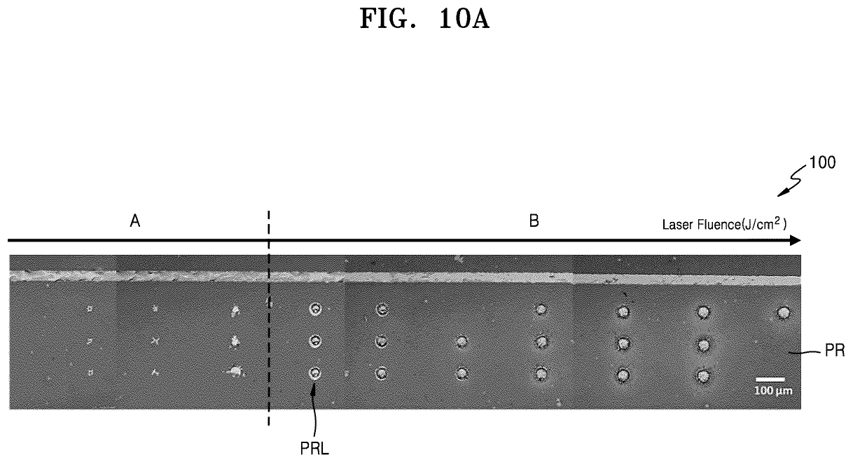

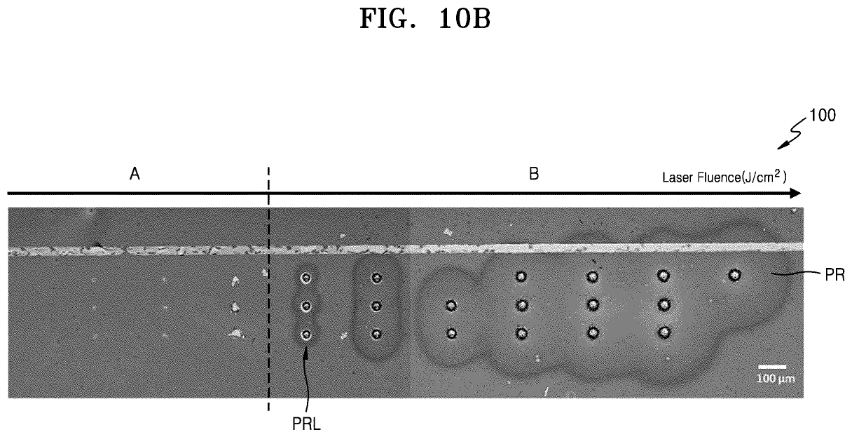

FIGS. 10A and 10B are diagrams of etching results using a photoresist pattern according to the fluence of a laser used for irradiation. In FIGS. 10A and 10B, area A may refer to an area not irradiated with a laser, and area B may refer to an area irradiated with a laser. In addition, in area B, an arrow direction may indicate the fluence of the laser used for irradiation.

In FIG. 10A, the photoresist film PR may first be formed on the substrate 100. The method of forming the photoresist film PR in FIG. 10A may be performed by the same method under the same conditions as the method of forming the photoresist film PR described above with reference to FIG. 8A.

Next, laser irradiation may be performed on the photoresist film PR. In FIG. 10A, area A may not be irradiated with a laser and area B may be irradiated with a laser. The laser irradiation may be performed for about 0.05 seconds using a UV laser. The fluence of the laser used for irradiation may also increase from 0.3 J/cm² to about 1.2 J/cm² in the arrow direction. The laser irradiation may be performed only on a portion of area B rather than the entire area B, and the portion of area B irradiated with the laser may be referred to as a laser-irradiated area PRL.

Referring to FIG. 10B, an ashing process may be performed on the result of FIG. 10A. The ashing process may be performed by the same method under the same conditions as the ashing process described above with reference to FIG. 8B.

Referring to the result of FIG. 10B, it may be seen that the photoresist film PR is removed by the ashing process in area A not irradiated with the laser, while the photoresist film PR remains in an area adjacent to the laser-irradiated area PRL in area B. That is, it may be seen that the etch resistance of the photoresist film PR is enhanced by laser irradiation.

In addition, referring to the result of FIG. 10B, it may be seen that as the laser fluence increases from 0.3 J/cm² to about 1.2 J/cm², the photoresist film PR, which is not removed by the ashing process, increases, in area B.

While the inventive concept has been particularly shown and described with reference to embodiments thereof, it will be understood that various changes in form and details may be made therein without departing from the spirit and scope of the following claims.

What is claimed is:

1. A method of enhancing etch resistance of a photoresist pattern, the method comprising:
forming a photoresist film comprising a photoresist composition comprising a polymer;
forming a photoresist pattern by patterning the photoresist film; and
irradiating the photoresist pattern with a laser, wherein the etch resistance of the photoresist pattern irradiated with the laser is enhanced.

2. The method of claim 1, wherein the polymer in the photoresist composition comprises an acrylate-based polymer.

3. The method of claim 1, wherein the irradiating of the photoresist pattern with the laser is performed without creating a separate chamber atmosphere for laser irradiation.

4. The method of claim 1, wherein the laser comprises an ultraviolet (UV) laser or a continuous-wave laser.

5. The method of claim 1, wherein the laser irradiation is performed at room temperature.

6. The method of claim 1, wherein the fluence of the laser is from about 0.3 J/cm² to about 1.2 J/cm².

7. The method of claim 1, wherein the irradiation time of the laser is from about 0.05 seconds to about 2 seconds.

8. A method of manufacturing a semiconductor device, the method comprising:
forming a feature layer;
forming, on the feature layer, a photoresist film comprising a photoresist composition comprising a polymer;
forming a photoresist pattern by patterning the photoresist film;
irradiating the photoresist pattern with a laser; and
processing the feature layer using the photoresist pattern irradiated with the laser, wherein the etch resistance of the photoresist pattern irradiated with the laser is enhanced.

9. The method of claim 8, wherein the polymer in the photoresist composition comprises an acrylate-based polymer.

10. The method of claim 8, wherein the laser comprises an ultraviolet (UV) laser or a continuous-wave laser.

11. The method of claim 8, wherein the irradiation time of the laser is about 0.05 seconds to about 2 seconds.

12. The method of claim 8, wherein the laser comprises a UV laser or a continuous-wave laser.

13. The method of claim 8, wherein the fluence of the laser is about 0.3 J/cm² to about 1.2 J/cm².

14. The method of claim 8, wherein the laser irradiation is performed at room temperature.

15. The method of claim 8, wherein the processing of the feature layer is performed using reactive ion etching (RIE).

16. A method of enhancing etch resistance of a photoresist pattern, the method comprising:
forming a photoresist film comprising a photoresist composition comprising an acrylate-based polymer;
forming a photoresist pattern by patterning the photoresist film; and
irradiating the photoresist pattern with a laser, wherein the irradiating of the photoresist pattern with the laser is performed without creating a separate chamber atmosphere for laser irradiation, and the etch resistance of the photoresist pattern irradiated with the laser is enhanced.

17. The method of claim 16, wherein the laser irradiation is performed at room temperature, and the fluence of the laser is about 0.3 J/cm² to about 1.2 J/cm².

18. The method of claim 16, wherein the acrylate-based polymer comprises polymethyl methacrylate.

19. The method of claim 16, wherein the photoresist composition is for extreme ultraviolet (EUV) photolithography.

20. The method of claim 16, wherein the irradiation time of the laser is from about 0.05 seconds to about 2 seconds.
